(19) United States
(12) Patent Application Publication
(10) Pub. No.: US 2009/0002032 A1
(43) Pub. Date: Jan. 1, 2009

(54) DATA SYNCHRONIZER

(76) Inventors: Abhishek Srivastava, Bangalore (IN); Amol Kshirsagar, Bangalore (IN); Charles E. Dike, Hillsboro, OR (US)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 11/769,627

(22) Filed: Jun. 27, 2007

(51) Int. Cl. H03K 19/00

(52) U.S. Cl. 326/93

(57) ABSTRACT

A data synchronizer is to avoid the pulse width constraint on the data while synchronizing the data between two devices operating at different clock rates. The data synchronizer may comprise one or more storage units such as the flip-flops and a clock gating logic associated with each storage unit. The clock gating logic may generate a control signal which may either allow or stall the clock reaching the storage units. The control signal may be generated by comparing the input and the output to the storage units.

### BACKGROUND

A data synchronizer may couple two devices that operate at different clock rates. A data synchronizer of a second device, which receives input signal from a first device, may synchronize the input signal with the clock of the second device. One or more data synchronizers may be provisioned in a microprocessor. The width of the input signal (data signal) may be constrained to enable accurate transfer of the data signal from the first device to the second device.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1A illustrates a processor 100 comprising a data synchronizer 101.

FIG. 1B depict waveforms generated by the data synchronizer 101 while the width of the data signal is not constrained.

FIG. 1C depict waveforms generated by the data synchronizer 101 while the width of the data signal is constrained.

FIG. 2A illustrates an embodiment of a processor 200 comprising a data synchronizer 201.

FIG. 2B illustrate waveforms generated by the data synchronizer 201.

### DETAILED DESCRIPTION

The following description describes a data synchronizer providing high throughput. In the following description, numerous specific details such as logic implementations, resource partitioning, or sharing, or duplication implementations, types and interrelationships of system components, and logic partitioning or integration choices are set forth in order to provide a more thorough understanding of the present invention. It will be appreciated, however, by one skilled in the art that the invention may be practiced without such specific details. In other instances, control structures, gate level circuits, and full software instruction sequences have not been shown in detail in order not to obscure the invention. Those of ordinary skill in the art, with the included descriptions, will be able to implement appropriate functionality without undue experimentation.

References in the specification to “one embodiment”, “an embodiment”, “an example embodiment”, indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device).

For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, and digital signals). Further, firmware, software, routines, and instructions may be described herein as performing certain actions. However, it should be appreciated that such descriptions are merely for convenience and that such actions in fact result from computing devices, processors, controllers, and other devices executing the firmware, software, routines, and instructions.

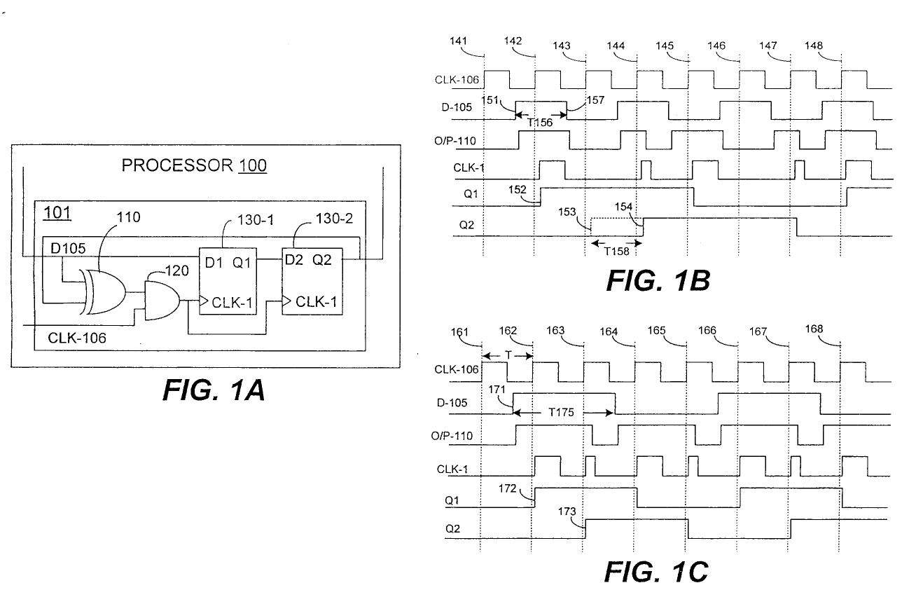

A processor 100 is illustrated in FIG. 1A. The processor 100 may comprise one or more data synchronizers such as the data synchronizer 101. In other embodiment, a system-on-chip (SoC) may also comprise data synchronizers. The data synchronizer 101 is shown comprising an X-OR logic 110, AND logic 120, and a storage unit such as D-Flip flops (FF) 130-1 and 130-2. The X-OR logic 110 may receive the inputs, respectively, from the data signal D-105 and the Q2 output of the FF130-2. The AND logic 120 may receive the inputs, respectively, from the output port of the X-OR logic 110 and the clock signal CLK-106. The D-FF 130-1 and 130-2 receive the clock signal CLK-1 from the output of the AND logic 120. The D input to the FF130-1 is provided by the data signal D-105 and the output Q1 of the FF130-1 is provided as an input to the FF 130-2.

FIG. 1B depicts the waveforms at different points of the data synchronizer 101. The clock signal CLK-106 depicts rising edges at time points 141 to 148. The output O/P-110 of the X-OR logic 110 is logic 1 if the inputs are not equal and the output is logic 0 otherwise. Thus, the O/P-110 is shown as logic 1 while D-105 and Q2 are not equal and is shown as logic 0 otherwise. The output of the AND logic 120 follows the CLK-106 if O/P-110 is logic 1 and the output of the AND logic 120 is logic 0 otherwise. Thus, CLK-1 depicts pulses with the width of each pulse equaling the time duration during which the O/P-110 and CLK-106 are logic 1.

The data signal D-105 depicts a transition to logic 1 at 151 and the pulse width of D-105 is T156. The pulse width T156 may equal one clock period T of CLK-106. The output Q1 of the FF130-1 transitions to logic 1 at 152 in response to receiving the transition in CLK-1. As depicted, the output Q2 of the FF130-2 may transition to logic 1 at time point 154 in response to receiving the CLK-1 at time point 144. The transition of Q2 is delayed by a period T158 (=T) and the delay or the latency T158 may equal the difference of time points 154 and 153. As a result, the transition in D-105 at time point 157 is not transferred to the output Q2 or the transition at 157 is swallowed by the data synchronizer 101. Therefore, the output Q2 is in error.

FIG. 1C depicts the waveforms at different points of the data synchronizer 101. The clock signal CLK-106 depicts rising edges at points 161 to 168. The data signal D-105 depicts a transition to logic 1 from logic 0 at 171 and the pulse width of D-105 equals T175. The pulse width T175 may equal 2T, where T is the period of one cycle of CLK-106. The output Q1 of the FF130-1 transitions to logic 1 from logic 0 at 172 in response to receiving the CLK-1. As depicted, the output Q2 of the FF130-2 may transition to logic 1 from logic 0 at 173 in response to receiving the CLK-1 at time point 163. However, the data signal D-105 may be maintained at logic 1 for the duration T175 to generate an accurate output Q2. The time duration T175 is greater than the time duration T156 and the width of the D-105 is thus constrained to at least T175 to generate an accurate output Q2.

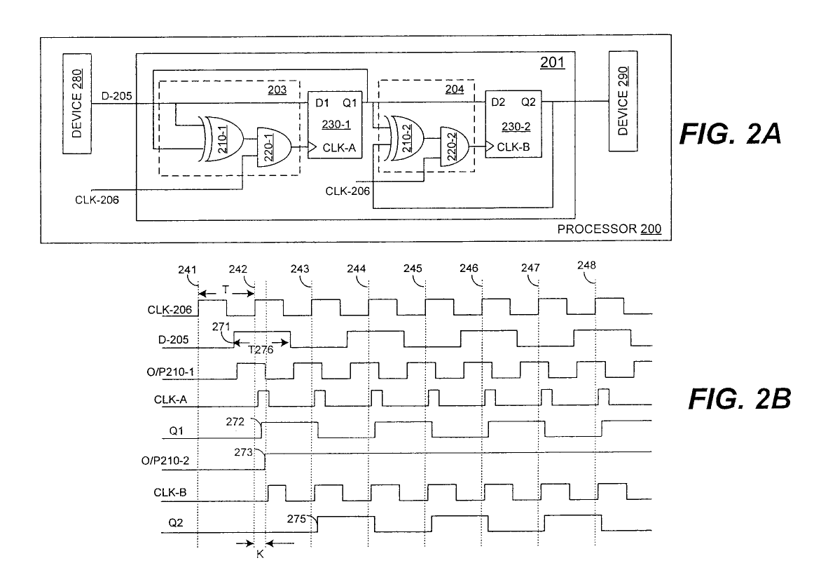

FIG. 2A illustrates a processor 200 comprising a data synchronizer 201 providing high throughput. In one embodiment, the data synchronizer 201 may be used to synchronize data between a first and a second device, which may be operating at different clock rates R1 and R2. In one embodiment, the first device and the second device may be referred to as operating in different clock domains. In one embodiment, the data synchronizer 201 may receive the data signal D-205 from a device 280 operating at a clock rate R1. In one embodiment, the data synchronizer 201 may synchronize the data signal D-205 with CLK-206 of rate R2 before providing the data signal to a device 290. In one embodiment, the data synchronizer 201 may avoid the constraint on the width of the data signal D-205.

In one embodiment, the data synchronizer 201 may comprise multiple sections with each section comprising a storage unit and a clock gating logic. In one embodiment, the data synchronizer 201 may comprise a storage unit such as a Flip-Flop (FF) 230-1 associated with a clock gating logic 203 in a first section and a Flip-Flop (FF) 230-2 associated with a clock gating logic 204 in a second section. In one embodiment, the FF230-1 and 230-2 may comprise a meta-hardened flops comprising low data resolution time or high mean time between failures (MTBF). In one embodiment, the constraint on the pulse width of the data signal D-205 may be avoided by providing a separate clock gating logic, which generate clock signal based on comparison of the input and output of each flip-flop 230.

In one embodiment, the clock gating logic 203 may be used to generate a control signal based on the comparison of the input data signal D-205 and the output Q1. In one embodiment, the control signal may stall or stop the clock signal reaching the flip-flop 230-1 if the data signal D-205 equals Q1. In one embodiment, the clock gating logic 203 may comprise an X-OR logic 210-1 and a AND logic 220-1. The X-OR logic 210-1 may receive data signal D-205 and Q1, which is the output of the FF 230-1 as the inputs. The X-OR logic 210-1 may generate a control signal such as an output O/P210-1, which may equal a logic 1 if D-205 and Q1 are unequal and a logic 0 if D-205 and Q1 are equal. The output (O/P210-1) of the X-OR logic 210-1 is coupled to the input of the AND logic 220-1.

In one embodiment, the AND logic 220-1 may receive O/P210-1 and the clock signal CLK-206 as the inputs. The AND logic 220-1 may generate one or more pulses and the width of each pulse may equal a period during which both the O/P210-1 and CLK-206 are logic 1. The FF230-1 may receive D-205 as the data input D1 and the output of the AND logic 220-1 as the clock input CLK-A. The FF230-1 may transfer the logic level on D-205 to the output Q1 in response to the changes in the logic level of the CLK-A.

In one embodiment, the clock gating logic 204 may be used to compare the input signal received at D2 (=Q1) and the output Q2 of the FF230-2. In one embodiment, the clock gating logic 204 may prevent the clock signal from reaching the flip-flop 230-2 if Q1 equals Q2. The X-OR logic 210-2 may receive Q1 and Q2 as its inputs and may generate an output O/P210-2, which may equal logic 1 if Q1 is not equal to Q2 and logic 0 otherwise. In one embodiment, the AND logic 220-2 may receive O/P210-2 and a clock signal CLK-206 as the inputs. In one embodiment, the AND logic 220-2 may generate CLK-B, which may comprise one or more pulses. In one embodiment, the width of each pulse may equal a period during which both the CLK-206 and O/P210-2 are logic 1.

In one embodiment, the FF230-2 may receive the output Q1 of the FF230-1 as data input (D2) and the output of clock gating logic 204 as the clock signal CLK-B. The FF230-2 may generate an output Q2, which may track the input signal received at D2 based on the occurrence of transition in the clock CLK-B.

FIG. 2B depicts the waveforms at different points of the data synchronizer 201. In one embodiment, the clock signal CLK-206 depicts rising edges at points 241 to 248. In one embodiment, the data signal D-205 depicts a transition to logic 1 from logic 0 at a time point 271. In one embodiment, the width of the pulse D-205 may equal T276. The pulse width T276 may equal T, where T is the period of one clock cycle of CLK-206.

Assuming that the output Q1 is at logic 0 during initialization, the output O/P210-1 may transition to logic 1 at time point 271 in response to the transition in D-205. While O/P210-1 and CLK-206 are logic 1, the AND logic 220-1 may generate a pulse of width duration K, which may be provided as CLK-A to the FF230-1. In one embodiment, the output Q1 of the FF230-1 may transition to logic 1 at time point 272 in response to the transition in the CLK-A.

Assuming that the output Q2 is at logic 0 during initialization, the output O/P210-2 may transition to logic 1 at time point 273 in response to the transition in Q1 at 272. The O/P210-2 may be held at logic 1 for the remaining time period as the inputs Q1 and Q2 to the X-OR logic 210-2 complement each other. As a result, the AND logic 220-2 may generate a train of pulses, which may approximately follow the clock signal CLK-206.

In one embodiment, the FF230-1 and 230-2 may receive a transition in the signal CLK-A and CLK-B at least once during each cycle of the clock signal CLK-206, except the first clock cycle. In one embodiment, the FF230-1 and 230-2 may transfer the input logic level to the output with a latency of one cycle. In one embodiment, the output Q1 of the FF230-1 may track the data signal D-205 with a latency of one cycle. In one embodiment, the output Q2 of the FF230-2 may track the output Q1 with a latency of one cycle. In one embodiment, the FF230-2 may not be triggered until one cycle after the FF230-1 is triggered.

Thus, the occurrence of error in the output as depicted in FIG. 1B and the constraint on the width of the data signal as depicted in FIG. 1C may be avoided. In one embodiment, triggering the FF230-2 after one cycle after triggering the FF230-1 may cause power savings. Also, the power saving may be achieved due to reduction in the number of clock cycles to transfer data signal.

Certain features of the invention have been described with reference to example embodiments. However, the description is not intended to be construed in a limiting sense. Various modifications of the example embodiments, as well as other embodiments of the invention, which are apparent to persons skilled in the art to which the invention pertains are deemed to lie within the spirit and scope of the invention.

What is claimed is:

1. An apparatus comprising:
a first storage unit, wherein the first storage unit is to transfer data at a first clock rate after receiving the data transferred at a second clock rate,
a second storage unit coupled to the first storage unit, wherein the second storage unit is to receive the data from the first storage unit and transfer the data at the first clock rate,
a first clock gating logic coupled to the first storage unit, wherein the first clock gating logic is to generate a first clock signal provided to the first storage unit, and
a second clock gating logic coupled to the second storage unit, wherein the second clock gating logic is to generate a second clock signal provided to the second storage unit.

2. The apparatus of claim 1, wherein the second storage unit is to be triggered one cycle after the first storage unit is triggered.

3. The apparatus of claim 1, wherein the rate of occurrence of the first clock signal and the second clock signal is to prevent the constraint on the pulse width of the data.

4. The apparatus of claim 3, wherein the first clock signal is provided to the first storage unit independent of the second clock signal provided to the second storage unit.

5. The apparatus of claim 1 the first clock gating logic further comprises a first logic element, wherein the first logic element is to generate a first control signal by comparing the data and the output signal of the first storage unit, which are provided as inputs to the first logic element.

6. The apparatus of claim 5, the first clock gating logic further comprises a second logic element coupled to the first logic element, wherein the second logic element is to allow the first clock signal to reach the first storage unit if the first control signal is of a first logic level.

7. The apparatus of claim 6, wherein the first logic element is an X-OR logic and the second logic element is a AND logic.

8. The apparatus of claim 1 the second clock gating logic further comprises a third logic element, wherein the third logic element is to generate a second control signal by comparing the output of the first storage unit and the output signal of the second storage unit, which are provided as inputs to the third logic element.

9. The apparatus of claim 8, the second clock gating logic further comprises a fourth logic element coupled to the third logic element, wherein the fourth logic element is to allow the second clock signal to reach the second storage unit if the second control signal is of a first logic level.

10. The apparatus of claim 9, wherein the third logic element is an X-OR logic and the fourth logic element is a AND logic and the first storage unit and the second storage unit comprises a D-type flip-flop.

11. A system comprising:
a first device, wherein the first device is to operate at a first clock rate,
a second device coupled to the first device, wherein the second device is to operate at a second clock rate, and
a synchronizer interposed between the first device and the second device, wherein the synchronizer is to avoid the pulse width constraint on data transferred from the first device to the second device.

12. The system of claim 11, the synchronizer further comprises:
a first storage unit, wherein the first storage unit is to transfer data at a first clock rate after receiving the data transferred at a second clock rate,
a second storage unit coupled to the first storage unit, wherein the second storage unit is to receive the data from the first storage unit and transfer the data at the first clock rate,
a first clock gating logic coupled to the first storage unit, wherein the first clock gating logic is to generate a first clock signal provided to the first storage unit, and
a second clock gating logic coupled to the second storage unit, wherein the second clock gating logic is to generate a second clock signal provided to the second storage unit.

13. The system of claim 12, wherein the second storage unit is to be triggered one cycle after the first storage unit is triggered.

14. The system of claim 13, wherein the first clock signal is provided to the first storage unit independent of the second clock signal provided to the second storage unit.

15. The system of claim 12, the first clock gating logic further comprises a first logic element, wherein the first logic element is to generate a first control signal by comparing the data and the output signal of the first storage unit, which are provided as inputs to the first logic element.

16. The system of claim 15, the first clock gating logic further comprises a second logic element coupled to the first logic element, wherein the second logic element is to allow the first clock signal to reach the first storage unit if the first control signal is of a first logic level.

17. The system of claim 16, wherein the first logic element is an X-OR logic and the second logic element is a AND logic.

18. The system of claim 12, the second clock gating logic further comprises a third logic element, wherein the third logic element is to generate a second control signal by comparing the output of the first storage unit and the output signal of the second storage unit, which are provided as inputs to the third logic element.

19. The system of claim 18, the second clock gating logic further comprises a fourth logic element coupled to the third logic element, wherein the fourth logic element is to allow the second clock signal to reach the second storage unit if the second control signal is of a first logic level.

20. The system of claim 18, wherein the third logic element is an X-OR logic and the fourth logic element is a AND logic, and the first storage unit and the second storage unit comprises a D-type flip-flop.
